(19) United States
(12) Patent Application Publication
(10) Pub. No.: US 2026/0090339 A1
(43) Pub. Date: Mar. 26, 2026

(54) CHIP ASSEMBLY WITH SHARED TESTING AND BUMPING PADS

(71) Applicant: Advanced Micro Devices, Inc., Santa Clara, CA (US)

(72) Inventor: John J. WUU, Fort Collins, CO (US)

(21) Appl. No.: 18/891,995

(22) Filed: Sep. 20, 2024

(51) Int. Cl. H01L 21/66; H01L 25/065; H10B 80/00

(52) U.S. Cl. CPC H10P 74/273; H10B 80/00; H10W 90/00; H10W 90/722

(57) ABSTRACT

Disclosed herein are an integrated circuit die assembly and a method for forming the integrated circuit die assembly. The integrated circuit die assembly includes an integrated circuit (IC) die stack comprising a top IC die and a bottom IC die. The top IC die includes a first layout of shared contact pads that are arranged identically to a second layout of shared contact pads disposed on the bottom IC die, the shared contact pads being configured for both contacting with a testing probe and bumping. The integrated circuit die further includes a package substrate coupled with the bottom IC die. The shared contact pads of the top IC die include probing marks, and the shared contact pads of the bottom IC die are coupled with solder bumps.

### TECHNICAL FIELD

Embodiments of the present invention generally relate to an integrated circuit chip assembly with shared testing and bumping pads, and, more particularly, relate to an integrated circuit chip assembly having shared testing and bumping pads in top and bottom integrated circuit chips.

### BACKGROUND

To meet the ever increasing demand on processing capabilities of integrated circuit (IC) devices, chip assembly schemes often form a 3D IC die stack by vertically mounting a plurality of IC dice. In one example, a High-Bandwidth DRAM Memory (HBM) has four or even a greater number of DRAM memory chips vertically stacked to increase the memory capacity. In another example, similar CPUs or FPGAs chips may be stacked to increase the computing power of an integrated circuit chip assembly. In yet another example, a CPU chip, a communication chip, a power chip, and a memory chip can be stacked to integrated several processing functions in one IC chip assembly.

To ensure the electrical connection of an IC die before assembly, each IC die needs to be probed by a testing equipment. Once an IC die passes the test, it is identified as a Known Good Die (KGD) and is ready for assembly. A conventional testing process typically utilizes many testing probes to contact testing pads of an IC die to test the electrical connection of the IC die. The testing process by the testing probe can be very destructive to the testing pads as the testing probes will exert both a vertical penetrating movement and a horizontal sliding movement on the testing pads. The testing probes often cause scratches or other damages to the testing pads. These pad damages, due to their length or depth, have been positively correlated to long term reliability issues. As a result, the testing pads become useless for functioning as reliable electrical contacting points after the testing process. Thus, they are also called sacrificial pads.

As an IC die also needs electrical connections for input, output, power, or other functions, contact pads are formed in an IC die to provide contacting points. Both the testing pads and the contact pads are formed on the surface, such as the top metal layer, of an IC die. Furthermore, both the contact pads and the testing pads are often placed around the peripheral areas of an IC die to ease connection. A testing pad may need at least 40×40 um area. As the chips may need hundreds of these testing pads for testing the proper electrical connections of the circuitries, the testing pads, in their sacrificial nature, have wasted a sizable and precious area of an IC die. When the number of testing pads are increasing in the surface, it can leave the surface of an IC die without sufficient space for other connections.

Therefore, a need exists for an improved IC die and an IC die assembly that could accommodate an increasing number of testing pads and the contact pads.

### SUMMARY

Disclosed herein are an IC chip assembly, chip packages and a method for forming the IC chip assembly. In an example, the integrated circuit die assembly includes an integrated circuit (IC) die stack having a top IC die and a bottom IC die. The top IC die includes a first layout of shared contact pads that are arranged identically to a second layout of shared contact pads disposed on the bottom IC die, the shared contact pads being configured for both contacting with a testing probe and bumping. The integrated circuit die further includes a package substrate coupled with the bottom IC die. The shared contact pads of the top IC die include probing marks, and the shared contact pads of the bottom IC die are coupled with solder bumps.

According to various embodiments, the probing marks include scratches caused by a testing probe. The IC chip assembly may further include an intermediate IC die disposed between the top IC die and the bottom IC die, where two or more or even each of the top IC die, the intermediate IC die, and the bottom IC die functions as a memory die. The shared contact pads of the first layout are disposed on a top surface of the top IC die, while the shared contact pads of the second layout are disposed at a bottom surface of the bottom IC die. The shared contact pads of the second layout may be disposed at a peripheral area of the bottom IC die. The top IC die and the bottom IC die further include a power pad coupling to a power routing. The bottom IC die may have an identical function or configuration as the top IC die and is made from a same substrate as the top IC die.

In another example, the method includes disposing a first IC tie at a topmost tier of an IC die stack. The first IC die includes a first layout of shared contact pads disposed at a top surface of the first IC die, the shared contact pads of the first IC die having probing marks. The method further includes disposing a second IC die at a bottommost tier of the IC die stack. The second IC die includes a second layout of shared contact pads disposed at a bottom surface of the second IC die, the first layout and the second layout being identical and the shared contact pads being configured for both contacting with a testing probe and bumping. The method further includes coupling the first IC die with the second IC die, disposing a package substrate under the second IC die, and coupling the second IC die to the package substrate via the second layout of the shared contact pads.

In still another example, an integrated circuit die assembly is provided. The integrated circuit die assembly includes a top IC die and a bottom IC die. The bottom IC die is electrically coupled to the top IC die directly or via one or more intervening IC dies. The top IC die includes including a first layout of first shared contact pads arranged along a peripheral area of the top IC die. The first shared contact pads are configured for both contacting with a testing probe and bumping. The first shared contact pads include probe marks. The bottom IC die has to a second layout of second shared contact pads that is arranged identically to the first layout of first shared contact pads of the top IC die. The second shared contact pads are devoid of probe marks.

In yet another example, a chip package is provided. The chip package includes a package substrate, a compute IC die, and a memory stack. The compute IC die is mounted to the package substrate. The memory stack is coupled to the compute die via routings formed in the package substrate. The memory stack includes a top IC die and a bottom IC die. The top IC die includes a first layout of first shared contact pads arranged along a peripheral area of the top IC die. The first shared contact pads configured for both contacting with a testing probe and bumping. The first shared contact pads include probe marks. The bottom IC die has to a second layout of second shared contact pads. The bottom IC die is electrically coupled to the top IC die directly or via one or more intervening IC dies. The second layout of second shared contact pads is arranged identically to the first layout of first shared contact pads of the top IC die. The second shared contact pads are devoid of probe marks.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic exploded view of an integrated circuit die assembly, according to an embodiment of the present disclosure.

FIG. 2 illustrates a schematic cross-sectional view of the integrated circuit die assembly, according to an embodiment of the present disclosure.

FIG. 3A illustrates a schematic top view of a pad layout of an IC die, according to an embodiment of the present disclosure.

FIG. 3B illustrates a schematic top view of a pad layout of an IC die with shared testing and contact pads, according to an embodiment of the present disclosure.

FIG. 3C illustrates a schematic partial cross-sectional view of the IC die of FIG. 3A along lines A-A, according to an embodiment of the present disclosure.

FIG. 3D illustrates a schematic partial cross-sectional view of the IC die of FIG. 3B along lines B-B, according to an embodiment of the present disclosure.

FIG. 4A illustrates a schematic view of a bottom surface of a bottom IC die, according to an embodiment of the present disclosure.

FIG. 4B illustrates a schematic view of a top surface of a top IC die, according to an embodiment of the present disclosure.

FIG. 5A illustrates a method of assembling an IC die assembly, according to an embodiment of the present disclosure.

FIG. 5B illustrates a method of testing a plurality of IC dice, according to an embodiment of the present disclosure.

FIG. 6 depicts one example of the IC die assembly included in a chip package configured as a high bandwidth memory (HBM) device.

To facilitate understanding, identical reference numerals have been used, where possible, to designate identical elements that are common to the figures. It is contemplated that elements of one embodiment may be beneficially incorporated in other embodiments.

### DETAILED DESCRIPTION

Disclosed herein are an IC die and an IC die assembly having shared testing pads and contact pads. In an example, the IC die includes a pad layout having a set of pads shared by a testing process and a bumping process. In an embodiment, the shared pad is capable of providing electrical connections for both die testing and solder bumping. The IC die as set forth in various embodiments of the present disclosure has a reduced contacting area occupied by the testing pads and the bumping pads. Examples in the present disclosure make a compromise that reuses the same pad for probing and bumping. When an IC chip assembly has a Face-to-Face design with dies facing the substrate, the bottom die needs to be bumped, while the top die doesn't. Thus, the probing of the bottom die may be skipped, allowing the bump pads to remain smooth for bumping. While examples of the IC chip assembly may limit testing to the top die, it is an acceptable balances between a null-set design that cannot accommodate both pad types and not testing either die.

In an example, an IC die having shared testing pads and contact pads will be disposed at different tiers of an IC die assembly depending on whether the shared pads are used for testing or bumping. When the set of shared pads are used for testing (tested die), a tested IC die is disposed at a tier, such as a top tie, where the set of shared pads will not be used for bumping anymore. When the set of shared pads are used for bumping, an IC die (untested die) will skip the testing process and be placed at any tier of the IC die assembly, such as the bottom tier. In an embodiment, the untested IC die, which skips the testing process, may have substantially the same configuration and come from the same substrate as the tested IC die so that the reliability of the bottom die may be fairly indicated by the top die. An IC die assembly may have the tested IC die disposed at the top tier and the untested IC die disposed at the bottom tier. The IC die assembly as set forth in various embodiment of the present disclosure can save more areas for non-testing related electrical connections and also reasonably ensures that the untested IC die has proper electrical connections.

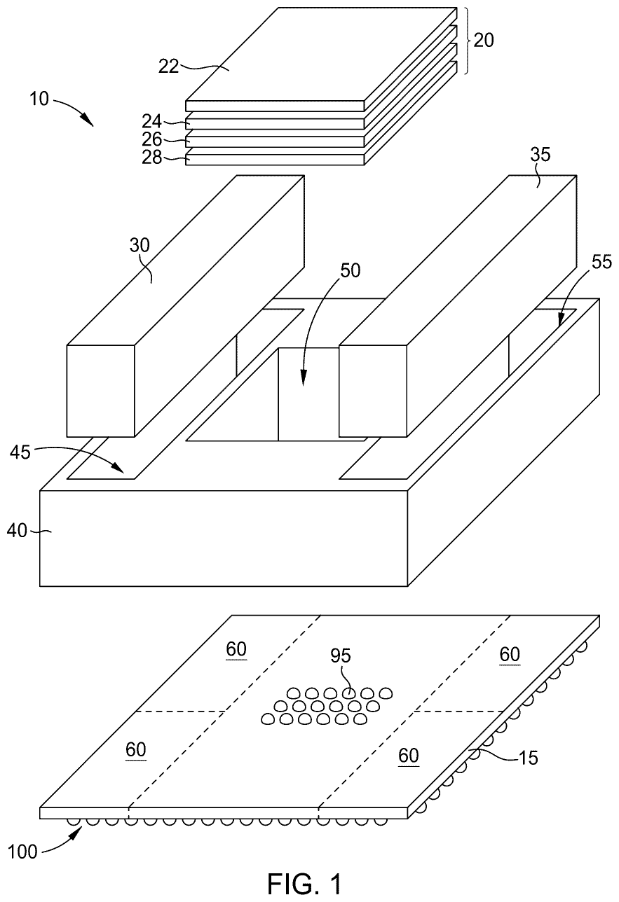

FIG. 1 illustrates a schematic exploded view of an integrated circuit (IC) die assembly, according to an embodiment of the present disclosure. The IC die assembly 10 includes an IC stack 20 coupled to a package substrate 15. The IC stack 20 includes a plurality of IC chips 22, 24, 26 and 28. Each of the IC chips 22, 24, 26, and 28 may be configured similarly with or differently from another IC chip. In an embodiment, one or more or even all of the IC chips 22, 24, 26 and 28 may function as memory chips and have substantially identical layouts. In another embodiment, at least the top IC chip 22 and the bottom IC chip 28 may have substantially identical layouts, while IC chips disposed between the top IC chip 22 and the bottom IC chip 28 may have different functions and layouts. In an embodiment, the top IC chip 22 and the bottom IC chip 28 include shared testing pads and bumping pads as set forth in various embodiments of the present disclosure. In other examples, at least one of the top IC chip 22 and the bottom IC chip 28 contains processor or logic circuity. For example at least one of the top IC chip 22 and the bottom IC chip 28 includes a central processing unit (CPU) or graphics processing unit (GPU). At least one of the top IC chip 22 and the bottom IC chip 28 may be configured as an application-specific integrated circuit (ASIC) or a field programmable gate array (FPGA). In other examples, the top IC chip 22 and the bottom IC chip 28 may be configured as the same type of IC chip or a different type of IC chip, and may be stacked with other IC chips (for example but not limited to IC chips 24, 26) of the same or different types as one or both of the top IC chip 22 and the bottom IC chip 28.

The IC die assembly 10 may include one or more dummy components 30 and 35, which are mounted on the package substrate 15. The dummy components 30 and 35 are mounted at select locations on the package substrate 15 for thermal management purposes. The dummy components 30 and 35 as well as the semiconductor chip stack 20 may be at least partially encased by a molding material 40. Various compartments 45, 50 and 55 in the molding material 40 are provided to accommodate the chip stack 20 and the dummy components 30 and 35.

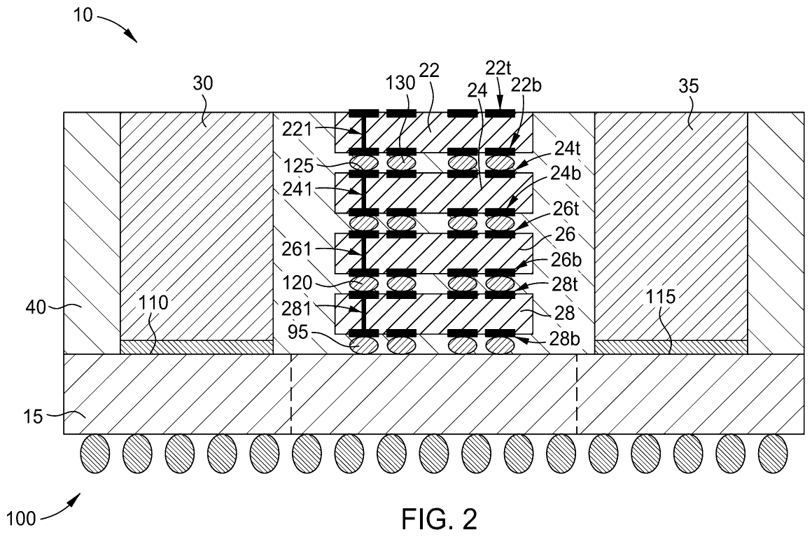

The package substrate 15 may include a plurality of processing units 60. The chip stack 20 is mounted on the package substrate 15 by electrical connections 95. The electrical connections 95 can be solder bumps, solder micro-bumps, conductive pillars, hybrid bonds, or other interconnects. To interface electrically with another component such as a circuit board or other device, the package substrate 15 can include plural I/O structures 100. The I/O structures 100 can be solder balls, solder bumps, conductive pillars, or other types of interconnect structures. FIG. 2 illustrates a schematic cross-sectional view of the IC die assembly 10 of FIG. 1. The dummy components 30 and 35 are thermally and mechanically connected to the package substrate 15 by thermal interface films 110 and 115. The bottom IC chip 28 of the chip stack 20 is electrically connected and mechanically mounted to the package substrate 15 by the electrical connections 95. The IC chip 26 can be secured to the IC chip 28 by electrical connections 120, which may be similarly configured as electrical connections 95. Similar electrical connections 125 and 130 can be positioned between the IC chips 24 and 26, between IC chips 22 and 24. The IC chips 22, 24, 26 and 28 may include through-silicon-vias (TSV) 221, 241, 261, 281 to provide through-chip pathways. The TSVs provide vertical connectivity for IC dice of different tiers. The TSVs may transfer several types of signals, including power, ground connection, data signal, testing signals, control signal, timing signal, encryption signal, or any other signals transmitted from a die to another die. In this way, data can be shared between the chips 22, 24, 26 and 28 and with the package substrate 15. The TSVs coupled with contact pads for transmitting power signals to various circuitries in different IC dice.

The electrical connections 95, 120, 125 and 130 can take on a variety of forms. For example, some of the electrical connections may be bumped with solder. Some of the electrical connections may include conductive pillars on each of two adjacent stacked chips, which can be thermal compression bonded. In another arrangement, direction oxide bond and TSV last connection can be used. In this technique, facing sides of each two adjacent stacked chips each receive an oxide film. The oxide films are subsequently planarized using chemical mechanical polishing and then plasma treated to become hydrophilic. The oxide surfaces are next placed together and annealed to form a bond. Thereafter, one of the chips is thinned by backgrinding. TSV etches and metal deposition or plating are then used to establish TSVs in contact with various I/O pads of each chip. In yet another alternative arrangement, a hybrid bonding technique is used.

In an embodiment, the IC chips 22, 24, 26, and 28 include contact pads 22t, 22b, 24t, 24b, 26t, 26b, 28t, 28b disposed on top and bottom surfaces for connecting with another device, such as a bump, a testing probe, a conductive pillar, or any other device. For example, the bottom IC chip 28 has contact pads 28t disposed at the top surface and contact pads 28b disposed at the bottom surface. In an embodiment, the top surface functions as an active side, while the bottom surface functions as a backside of an IC chip. The top IC chip 22 also has contact pads 22t disposed at the top surface and contact pads 22b disposed at the bottom surface. In an embodiment, the contact pads of the top IC chip 22 includes at least one shared pad configured to provide a contacting location for both a testing probe and a bump. The contact pads of the bottom IC chip 28 also includes at least one shared pad configured to provide a contacting location for both a testing probe and a bump. In an embodiment, the through-silicon via 221, 241, 261, 281 are coupled with the contact pads disposed in each IC chip 22, 24, 26, 28.

In an embodiment, the contact pads are configured to contact a probing card or a microbump. The contact pads may have a size of at least 25×25 um with a pitch of at least 10 um. The contact pads are formed in a top metal layer of an IC die. The contact pads may be made of a metal, such as copper, aluminum, gold, or any other suitable conductive material. In one example, the contact pads are made of from aluminum.

The testing process by a testing probe can damage the surface of a pad. Thus, a contact pad shared by a testing probe and a bump is not suitable for receiving a bump after being contacted by a testing probe. In an embodiment, the chip stack 20 is configured to have identical IC chips disposed at the top, such as IC chip 22, and at the bottom, such as IC chip 28. In such a configuration, the top IC chip 22 will be tested to make sure that it is a known good die by using the shared contact pads 22t, while the testing of IC chip 28 will be skipped to save the shared contact pads 28b for connecting with a bump. As the shared contact pads 22t are not used for any other connections, any damages to their surfaces by a testing probe are acceptable. In an embodiment, the bottom IC chip 28 has an identical design as the top IC chip 22, having the same functionality, performance and reliability as the top IC chip 22. The bottom IC chip 28 may be made in a same substrate as the top IC chip 22. As a result, the electrical connection of the IC chip 28 after fabrication can be fairly believed to be the same as the top IC chip 22.

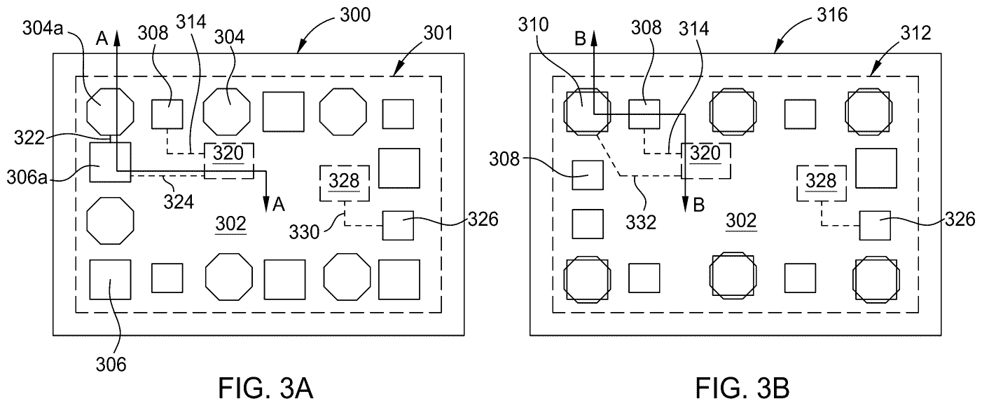

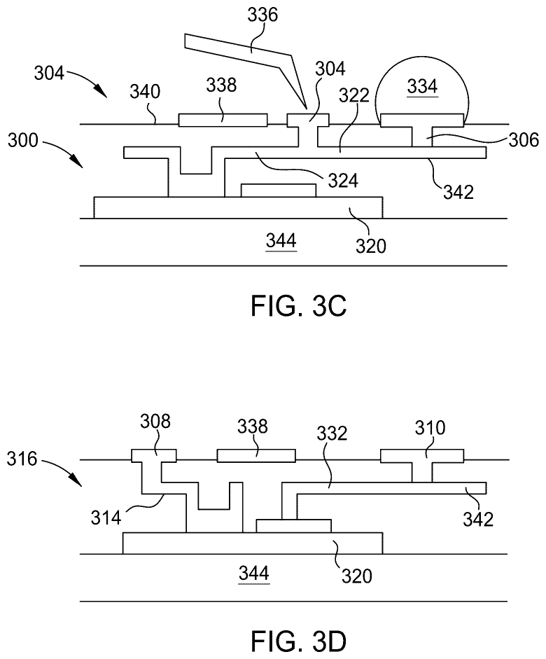

FIG. 3A illustrates a schematic top view of a pad layout 301 having separated testing pads and contact pads, according to an embodiment. The IC chip 300 has a top surface 302. A pad layout 301 includes a plurality of contact pads are disposed along the peripheral area on the top surface 302 of an IC die. The pad layout 301 includes different types of contact pads 304, 306, 308, such as testing pads 304, bumping pads 306, powering pads 308, and other suitable contact pads.

In an example, the plurality of testing pads 304 provide a connecting interface between an IC die and a testing instrument. The plurality of bumping pads 306 provide an interface among IC dice or between an IC die and a package substrate. The bumping pads 306 may couple to solder bumps or other connections. A testing pad 304 and a bumping pad 306 may be connecting for testing a circuitry 320. The circuitry 320 may include, but are not limited to, any one or more of transistors, diodes, resistors, capacitors, inductors, and memory cells, among others. A routing 322 may couple a testing pad 304a with a bumping pad 306a, and a routing 324 may couple the bumping pad 306a with the circuitry 320.

The plurality of power pads 308 provide an interface for power routings 314 that are configured to transmit power signals to circuitries of the IC chip 300. For example, a powering pad 308 may couple with the circuitry 320 via a routing 314 and provide power to the circuitry 320. Another power pad 326 may couple with another circuitry 328, which is disposed at a location different from the circuitry 320, via a routing 328. In an embodiment, the power pads 308 and 326 are coupled with TSVs 221 shown in FIG. 2.

It is contemplated that the number and types of contact pads in the layout 301 are not limited to what are shown in FIG. 3A and can be varied depending on functions of an IC die. As shown in FIG. 3A, the testing pads 304 and the bumping pads 306 have taken a large portion of the perimeter of the top surface 302. As a result, the number of the power pads 308 for power routings is limited.

FIG. 3B illustrates a schematic top view of a pad layout 312 of an IC chip 316 having shared testing pads and bumping pads, according to an embodiment. In embodiment, the surface 302 includes a plurality of shared contact pads 310, each of which can function as a testing pad 304 and a bumping pad 306. The shared contact pads 310 are coupled with the circuitry 320 via a routing 332. As the shared contact pads 310 combine the testing pads 304 and the bumping pads 306, the routing 322 is removed. The shared contact pads 310 can be used for contacting a testing probe to test the IC chip 316 and coupling to a bump for connecting the IC chip 316 with another device. When the testing pads 304 and the bumping pads 306 are combined into shared contact pads 310, the peripheral area of the surface 302 has more areas for holding other contact pads, such as the powering pads 308 that couple to the power routing 314. For example, the IC chip 316 in FIG. 3B has 8 power pads, which are 4 more than those in the IC chip 300 of FIG. 3A. In an embodiment, the top chip 22 and the bottom chip 28 of FIG. 2 include at least one shared pad 310 on their surfaces. The shared pads 310 on the top chip 22 are probed by a testing probe, while the shared pads 310 of the bottom chip 28 are not being probe so that they can be used for coupling to bumps or other connections.

FIG. 3B shows that the shared pads 310 are arranged along the periphery area of the surface 302. In an embodiment, the shared pads 310 may be spread across the entire area of surface 302. In an embodiment, the surface 302 may also include other types of contact pads, such as contact pads for power signals, contact pads for input and output of the IC chip 316, and any other suitable contact pads.

FIG. 3C illustrates a schematic partial cross-sectional view of the IC die 300 of FIG. 3A along lines A-A, according to an embodiment of the present disclosure. The IC die 300 includes a substrate 344 having the circuitry 320. The IC die 300 also includes routings 324 and 322 formed by metal traces formed in a metal layer 342. In an example, the bumping pad 306 and the testing pad 304 are disposed on a top surface 340 of the IC die 300 and formed in the top metal layer 338. A testing probe 336 is used to contact the testing pad 304 when the bare die 300 is tested for electrical connections. A bump 334 is disposed on the bumping pad 306 after the bare die 300 is determined to be a known good die. The routing 322 coupling the bumping pad 306 and the testing pad 304 and the routing 324 coupling the bumping pad 334 with the circuitry 320 may be formed by a metal layer 342 disposed under the top metal layer 340.

FIG. 3D illustrates a schematic partial cross-sectional view of the IC die 316 of FIG. 3B along lines B-B, according to an embodiment of the present disclosure. The IC die 316 includes a substrate 344 having the circuitry 320 and a routing 332 formed by metal traces formed in the metal layer 342. In an example, the testing pad 304 and the bumping pad 306 are combined to form a shared contact pad 310, which may be disposed at the same location as the bumping pad 306 or be disposed at a different location. A routing 332 is used to couple the shared contact pad 310 with the circuitry 320. In addition, the bar die 316 have a power pad 308 coupled with the circuity 320 via the routing 314.

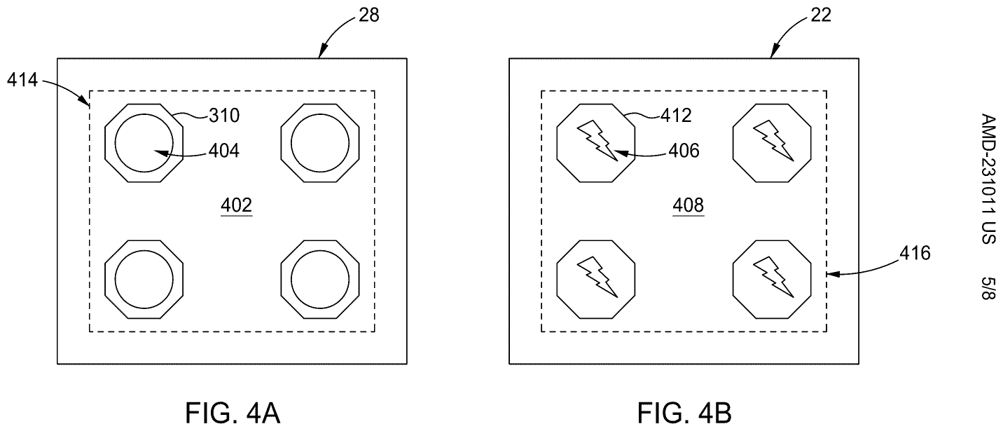

FIG. 4A illustrates a schematic view of a plurality of shared contact pads 310 of the bottom IC die 28, according to an embodiment. As the bottom IC die 28 is mounted on a package substrate (shown in FIG. 1), the shared contact pads 310 are disposed on a surface 402 facing the package substrate 15, which is the bottom surface of the bottom IC die 28. The shared contact pads 310 couple to solder bumps 404, which, in turn, couple to the package substrate 15 (shown in FIG. 1).

FIG. 4B illustrates a schematic view of a plurality of shared contact pads 412 of the top IC die 22, according to an embodiment. The shared contact pads 412 are not coupled to any other electrical connections because their surfaces have damages 406, such as scratches or depressions. The surface 408 of the top IC die 22 is the top surface of the top IC die 22.

In an embodiment, the pad layout 414 of the shared contact pads 310 of the bottom IC chip 28 is identical to the layout 416 of the shared contact pads 412 of the top IC chip 22. A layout of the contact pads includes the location, the pitch, the size, the quantity, and other parameters of the shared contact pads.

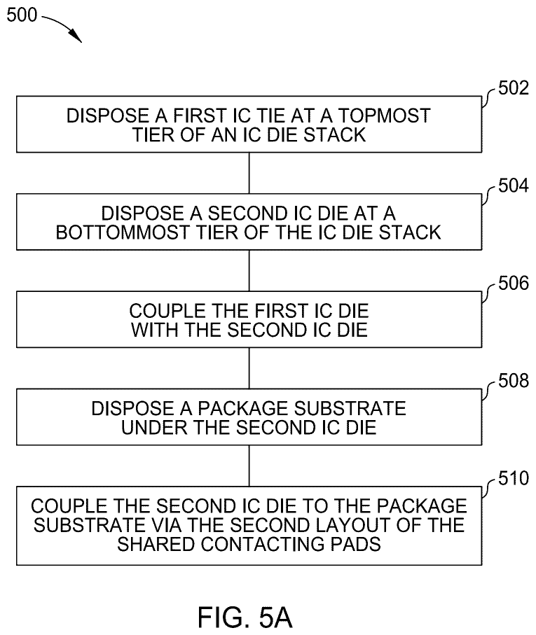

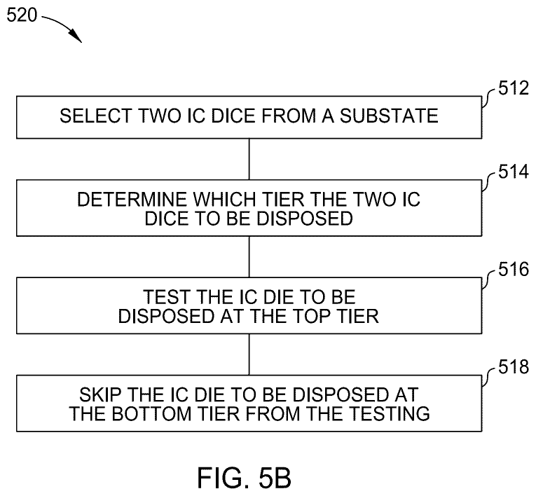

FIG. 5A illustrates a method 500 for forming an integrated circuit assembly, according to an embodiment of the present disclosure. At operation 502, a first IC tie is disposed at a topmost tier of an IC die stack. The first IC die includes a first layout of shared contact pads disposed at a top surface of the first IC die, the shared contact pads of the first IC die having probing marks. At operation 504, a second IC die is disposed at a bottommost tier of the IC die stack. The second IC die includes a second layout of shared contact pads disposed at a bottom surface of the second IC die, the first layout and the second layout being identical and the shared contact pads being configured for both contacting with a testing probe and bumping. At operation 506, the first IC die is coupled with the second IC die. At operation 508, a package substrate is disposed under the second IC die. At operation 510, the second IC die is coupled to the package substrate via the second layout of the shared contact pads.

The method may further include disposing, in the bottom IC die, a power pad coupling to a power routing. The method may include forming the first IC die and the second IC die in a same substrate, testing the first IC die with a testing probe for electrical connections, and causing the second IC die to skip a testing for a known good die. The method may further include disposing a third IC die between the first IC die and the second IC die and forming through-silicon-vias in the first IC die, the second IC die, and the third IC die. The through-silicon-vias are configured to couple a shared contact pad in the first die with a shared contact pad in the second die.

FIG. 5B illustrates a method for testing a plurality of IC dice, according to an embodiment of the present application. In an embodiment, the method 520 is used for testing a plurality of memory dice for forming an HBM. At operation 512, two memory dice are selected from a same substrate, which has been processed by a same processing flows. The two memory dice have identical pad layouts for connecting with other dice or a package. The pad layout includes a plurality of shared contact pads for both testing and bumping. At operation 514, one of the two dice is determined to be used at the top tier of an HBM, wherein the shared contact pads will not be used for connecting the top tie to another die or the package. Then, the other one of the two dice is determined to be used at the bottom tier of the HBM. At operation 516, the IC die at the top tier is probed by a testing equipment. Testing marks, such as scratches or penetrations, are formed by the testing probe. At operation 518, the IC die at the bottom tier is not probed by the testing equipment. Thus, the shared contact pads disposed on the IC die at the bottom of the tier is devoid of (i.e., free from) probe marks The two dice will be paired until being positioned in the HBM.

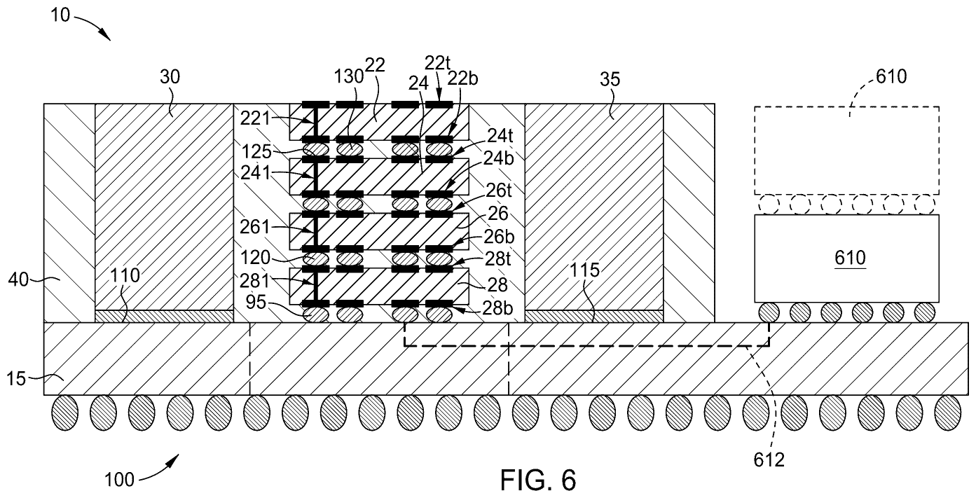

FIG. 6 depicts one example of the IC die assembly 10 included in a chip package 600 configured as a high bandwidth memory (HBM) device. The IC die assembly 10 generally include IC chips 22, 24, 26 and 28 arranged in a memory stack. One or more of the IC chips 22, 24, 26 and 28 may include a memory controller and/or I/O circuitry, the other of the IC chips 22, 24, 26 and 28 configured as volatile or non-volatile memory, such as dynamic random access memory (DRAM), ferroelectric random access memory (FeRAM) or other suitable type of memory.

One or more compute dies 610 are mounted to the package substrate 15 of the IC die assembly 10. The one or more compute dies 610 are coupled to the memory stack comprising IC chips 22, 24, 26 and 28 via routings 612 formed through the package substrate 15. At least a first compute die 610 of the compute dies 610 includes functional circuitry having central processing unit (CPU) cores and/or accelerated compute cores. The accelerated compute cores contained in the functional circuitry of the first compute die 610 generally include math engine circuitry. The math engine circuitry is generally designed for task specific computing, such as used data center computing, high performance computing and AI/ML computing. Thus, the first compute die 610 may also be referred to as a central processing unit (CPU) die, CPU chiplet, graphic processing unit (GPU) die or GPU chiplet. The functional circuitry of the first compute die 610 may also include System Management Unit (SMU) that is configured to monitor thermal and power conditions and adjust power and cooling to keep the first compute die 610 functioning as within specifications. The functional circuitry of the first compute die 610 may also include Dynamic Function eXchange (DFX) Controller IP circuitry. The DFX circuitry provides management of hardware or software trigger events. For example, the DFX circuitry may pull partial bitstreams from memory and delivers them to an internal configuration access port (ICAP). The DFX circuitry also assists with logical decoupling and startup events, customizable per Reconfigurable Partition.

In summary, the present disclosure provides various examples of an IC die assembly with an improved pad layout. In an example, the integrated circuit die assembly includes an integrated circuit (IC) die stack having a top IC die and a bottom IC die, the top IC die including a first layout of shared contact pads that are arranged identically to a second layout of shared contact pads disposed on the bottom IC die, the shared contact pads being configured for both contacting with a testing probe and bumping. The integrated circuit die assembly also includes a package substrate coupled with the bottom IC die. The shared contact pads of the top IC die have probing marks, and the shared contact pads of the bottom IC die are coupled with solder bumps.

In various examples, the integrated circuit die assembly includes an intermediate IC die disposed between the top IC die and the bottom IC die. Each of the top IC die, the intermediate IC die, and the bottom IC die functions as a memory die (i.e., contains a plurality of memory cells). In other examples, at least one of the top IC die, the intermediate IC die, and the bottom IC die contains processor or logic circuity. For example at least one of the top IC die, the intermediate IC die, and the bottom IC die includes a central processing unit (CPU) or graphics processing unit (GPU). At least one of the top IC die, the intermediate IC die, and the bottom IC die may be configured as an application-specific integrated circuit (ASIC) or a field programmable gate array (FPGA).

In yet other various examples, the shared contact pads of the first layout are disposed on a top surface of the top IC die. The shared contact pads of the second layout are disposed at a bottom surface of the bottom IC die. The shared contact pads of the second layout are disposed at a peripheral area of the bottom IC die. The top IC die further comprises a power pad coupling to a power routing. The probing marks include scratches and or depressions that are caused by a testing probe. The shared contact pads of the second layout are suitable for bumping.

In yet other various examples, the top IC die is a known good die. The bottom IC die has identical functions as the top IC die. The bottom IC die is made from a same substrate as the top IC die.

The present disclosure also provides various examples of a method for making an integrated circuit die assembly. The method includes disposing a first IC tie at a topmost tier of an IC die stack, the first IC die including a first layout of shared contact pads disposed at a top surface of the first IC die, the shared contact pads of the first IC die having probing marks. The method also includes disposing a second IC die at a bottommost tier of the IC die stack, the second IC die including a second layout of shared contact pads disposed at a bottom surface of the second IC die, the first layout and the second layout being identical and the shared contact pads being configured for both contacting with a testing probe and bumping. The method also includes coupling the first IC die with the second IC die; disposing a package substrate under the second IC die; and coupling the second IC die to the package substrate via the second layout of the shared contact pads.

In various examples, the method further includes disposing, in the bottom IC die, a power pad coupling to a power routing, testing the first IC die with a testing probe for electrical connections. The method may include forming the first IC die and the second IC die in a same substrate, causing the second IC die to skip a testing for a known good die, and disposing a third IC die between the first IC die and the second IC die. The method may also include forming through-silicon-vias in the first IC die, the second IC die, and the third IC die that are configured to couple a shared contact pad in the first IC die with a shared contact pad in the second IC die.

For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. Additionally, within a range includes every point or individual value between its end points even though not explicitly recited. Thus, every point or individual value may serve as its own lower or upper limit combined with any other point or individual value or any other lower or upper limit, to recite a range not explicitly recited.

All numerical values within the detailed description herein are modified by “about” the indicated value, and take into account experimental error and variations that would be expected by a person having ordinary skill in the art.

As is apparent from the foregoing general description and the specific embodiments, while forms of the present disclosure have been illustrated and described, various modifications can be made without departing from the spirit and scope of the present disclosure. Accordingly, it is not intended that the present disclosure be limited thereby. Likewise, the term “comprising” is considered synonymous with the term “including. ” Likewise whenever a composition, an element or a group of elements is preceded with the transitional phrase “comprising,” it is understood that we also contemplate the same composition or group of elements with transitional phrases “consisting essentially of,” “consisting of,” “selected from the group of consisting of,” or “is” preceding the recitation of the composition, element, or elements and vice versa.

While the foregoing is directed to embodiments of the present invention, other and further embodiments of the invention may be devised without departing from the basic scope thereof, and the scope thereof is determined by the claims that follow.

What is claimed is:

1. An integrated circuit die assembly comprising:
an integrated circuit (IC) die stack comprising a top IC die and a bottom IC die, the top IC die including a first layout of shared contact pads that are arranged identically to a second layout of shared contact pads disposed on the bottom IC die, the shared contact pads being configured for both contacting with a testing probe and bumping; and
a package substrate coupled with the bottom IC die,
wherein the shared contact pads of the bottom IC die are coupled with solder bumps to the top IC die or an IC die disposed between the top and bottom IC dies.

2. The integrated circuit die assembly of claim 1, further comprising an intermediate IC die disposed between the top IC die and the bottom IC die.

3. The integrated circuit IC die assembly of claim 2, wherein each of the top IC die, the intermediate IC die, and the bottom IC die functions as a memory die.

4. The integrated circuit die assembly of claim 1, wherein the shared contact pads of the first layout are disposed on a top surface of the top IC die.

5. The integrated circuit die assembly of claim 4, wherein the shared contact pads of the second layout are disposed at a bottom surface of the bottom IC die.

6. The integrated circuit die assembly of claim 5, wherein the shared contact pads of the second layout are disposed at a peripheral area of the bottom IC die.

7. The integrated circuit die assembly of claim 6, wherein the top IC die further comprises a power pad coupling to a power routing.

8. The integrated circuit die assembly of claim 1, wherein the shared contact pads of the top IC die further comprise probing marks, wherein the probing marks include scratches or depression.

9. The integrated circuit die assembly of claim 8, wherein the shared contact pads of the top IC die are fabricated from aluminum.

10. The integrated circuit die assembly of claim 5, wherein the shared contact pads of the second layout are suitable for bumping.

11. The integrated circuit die assembly of claim 1, wherein the shared contact pads of the top IC die comprise probing marks, and wherein the shared contact pads of the bottom IC die does not contain probing marks.

12. The integrated circuit die assembly of claim 11, wherein the bottom IC die has an identical function as the top IC die.

13. A method for making an integrated circuit die assembly, comprising:
disposing a first IC tie at a topmost tier of an IC die stack, the first IC die comprising a first layout of shared contact pads disposed at a top surface of the first IC die;
disposing a second IC die at a bottommost tier of the IC die stack, the second IC die comprising a second layout of shared contact pads disposed at a bottom surface of the second IC die, the first layout and the second layout being identical and the shared contact pads being configured for both contacting with a testing probe and bumping;
coupling the first IC die with the second IC die;
disposing a package substrate under the second IC die; and
coupling the second IC die to the package substrate via the second layout of the shared contact pads.

14. The method of claim 13, further comprising disposing, in the bottom IC die, a power pad coupling to a power routing.

15. The method of claim 13, further comprising:
testing the first IC die with a testing probe for electrical connections, the testing leaving probing marks on the shared contact pads of the first IC die.

16. The method of claim 15, further comprising:
forming the first IC die and the second IC die in a same substrate.

17. The method of claim 16, further comprising:
causing the second IC die to skip a testing for a known good die.

18. The method of claim 13, further comprising:
disposing a third IC die between the first IC die and the second IC die.

19. The method of claim 18, further comprising:
forming through-silicon-vias in the first IC die, the second IC die, and the third IC die that are configured to couple a shared contact pad in the first IC die with a shared contact pad in the second IC die.

20. A chip package comprising:
a package substrate;
a compute IC die mounted to the package substrate; and
a memory stack die mounted to the package substrate and coupled to the compute die via routings formed in the package substrate, the memory stack comprising:
a top IC die including a first layout of first shared contact pads arranged along a peripheral area of the top IC die, the first shared contact pads being configured for both contacting with a testing probe and bumping, the first shared contact pads including probe marks; and
a bottom IC die having to a second layout of second shared contact pads, the bottom IC die electrically coupled to the top IC die directly or via one or more intervening IC dies, the second layout of second shared contact pads arranged identically to the first layout of first shared contact pads of the top IC die, the second shared contact pads devoid of probe marks.
